(19) United States
(12) Patent Application Publication
(10) Pub. No.: US 2014/0103932 A1
(43) Pub. Date: Apr. 17, 2014

(54) SYSTEM AND METHOD FOR LIGHT INTENSITY MONITORING

(71) Applicant: ELECTRO-MOTIVE DIESEL, INC., LaGrange, IL (US)

(72) Inventor: Scott A. Swenson, Willowbrook, IL (US)

(73) Assignee: Electro-Motive Diesel, Inc., LaGrange, IL (US)

(21) Appl. No.: 13/649,289

(22) Filed: Oct. 11, 2012

(51) Int. Cl. G01R 31/44

(52) U.S. Cl. 324/414

(57) ABSTRACT

A system is provided. The system includes a light emitting diode and a monitoring module. The monitoring module is communicably coupled to the light emitting diode. The monitoring module is configured to receive one or more signals indicative of power consumption of the light emitting diode. Further, the monitoring module is configured to determine a condition of the light emitting diode based, at least in part, on the received signals.

### TECHNICAL FIELD

The present disclosure relates to monitoring system and more particularly to a system for monitoring operational health of a light emitting diode.

### BACKGROUND

Today's locomotives use incandescent bulbs in headlights and other auxiliary lights present on the locomotive. On failure, these incandescent lights do not give off light. In a situation wherein the incandescent lights are replaced with light emitting diodes, failure detection cannot be done in a similar manner. The light emitting diodes have a tendency to slowly dim and lose intensity over time. Hence, there is a need to monitor operational health and more importantly detect a condition of the light emitting diode.

U.S. Pat. No. 7,990,078 relates to a lighting control system suitable for a surgical lighting device. The lighting control system includes circuitry that compensates for the effects of temperature changes in a lighting device, and that compensates for forward voltage variations among LED lighting modules to provide substantially uniform light output.

### SUMMARY OF THE DISCLOSURE

In one aspect of the present disclosure a system is provided. The system includes a light emitting diode and a monitoring module. The monitoring module is communicably coupled to the light emitting diode. The monitoring module is configured to receive one or more signals indicative of power consumption of the light emitting diode. Further, the monitoring module is configured to determine a condition of the light emitting diode based, at least in part, on the received signals.

In another aspect, a method for monitoring operational health of a light emitting diode is provided. The method receives one or more signals indicative of power consumption of the light emitting diode. The method compares the power consumption of the light emitting diode with a pre-determined threshold. Further, the method determines a condition of the light emitting diode based on the comparison.

Other features and aspects of this disclosure will be apparent from the following description and the accompanying drawings.

### BRIEF DESCRIPTION OF THE DRAWINGS

FIG. 1 is a diagrammatic view of a front end of an exemplary locomotive, according to one embodiment of the present disclosure;

FIG. 2 is a block diagram of a monitoring system for a light emitting diode present on the machine; and

FIG. 3 is a flowchart for monitoring operational health of the light emitting diode.

### DETAILED DESCRIPTION

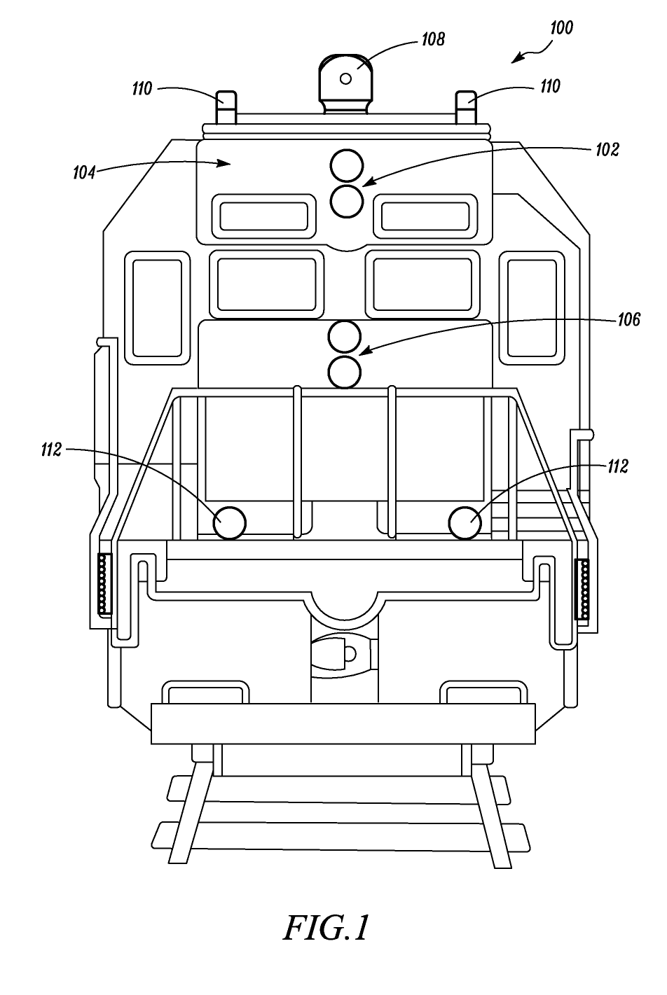

FIG. 1 is a diagrammatic view of a front end of an exemplary locomotive 100, according to one embodiment of the present disclosure. More particularly, FIG. 1 depicts the positioning of a headlight 102 and various alerting lights installed on the front end of the locomotive 100. As shown in FIG. 1, the headlights 102 may be mounted near a top portion of a crew cab 104 or below the crew cab 104 on a nose of the locomotive 100. The headlight 102 is typically designed to illuminate a track area directly in front of the locomotive 100. This may allow an operator to view a specified distance ahead of the locomotive 100 lin order to see signals and otherwise operate the locomotive 100 in a safe manner.

The alerting lights may include oscillating lights 106, beacon lights 108, strobe lights 110, ditch lights 112, and the like. For example, the oscillating light 106 may be mounted on the front end of the locomotive 100 and aimed down a track centerline. The beacon light 108 may be mounted on the top of the locomotive 100, as far front as possible, on the centerline of the locomotive 100. The strobe lights 110 may be positioned in pairs, one on each side, on a roof or on a lower front end of the locomotive 100. The ditch light 112 may be designed to illuminate a part of the track right-of-way lying outside an area normally illuminated by the headlight 102. The alerting lights are used to supply visual signals to the operator. These visual signals are formed by a light source which may differ in number, intensity, location on the locomotive, beam width, and focus angle.

In one embodiment, the headlight 102 and/or at least one of the alerting lights may include a plurality of light emitting diodes 202 (hereinafter referred to as LED). Moreover, in another embodiment, step lights (not shown in figures) located on the locomotive 100 where a person boards the locomotive 100 can also make use of the LED 202. It should be understood that additionally, other lights present on the locomotive 100 may include the LED 202.

A person of ordinary skill in the art will appreciate that the LED 202 operates differently from incandescent lights. For example, the incandescent light is considered failed or defective when the incandescent light no longer gives off light. However, the LED 202 does not fail in the similar manner. With usage over time, an intensity of the LED 202 may drop below a required pre-determined candela level specified for the locomotive 100.

The present disclosure relates to a monitoring module 204 for monitoring an operational health of the LED 202. The monitoring module 204 is configured to receive one or more signals indicative of power consumption of the LED 202. Further, the monitoring module 204 is configured to determine a condition of the LED 202 based, at least in part, on the received signals. The condition of the LED 202 may include a weak output state or failure of the LED 202, as the case may be.

It should be noted that in the present disclosure, the intensity of the LED 202 may be determined based on the power consumption of the LED 202. This metric may provide a substantially accurate estimate of the intensity of the LED 202 as against the usage of parameters like voltage, current, and the like. Also, it should be understood that the disclosure described herein may apply to any LED based lighting system making use of a plurality of the LEDs 202 arranged in a series configuration, parallel configuration or any other electrical configuration making use of either a single LED 202 or multiple LEDs 202.

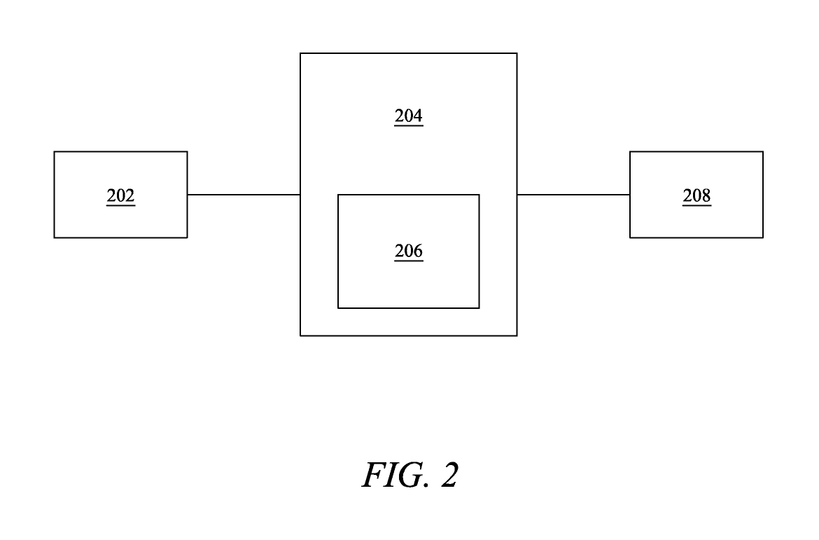

Referring to FIG. 2, the monitoring module 204 may be communicably coupled either directly or indirectly to the LED 202. In one embodiment, the monitoring module 204 may be coupled to an electronic controller present within the locomotive 100, which in turn is coupled to the LED 202. The monitoring module 204 is configured to receive the one or more signals indicative of the power consumption of the LED 202. In one embodiment, the one or more signals may include a voltage signal indicative of the voltage across the LED 202; and a current signal indicative of the current flowing through the LED 202. The power consumption of the LED 202 may be estimated based on these signals.

These signals may be received at a pre-determined time, in accordance with one embodiment of the present disclosure. One of ordinary skill in the art will appreciate that these signals may be measured using techniques known in the art. For example, a voltage sensing element and/or current sensing element, such as, a differential amplifier or other known circuitry may be used to generate signals indicative of the voltage and current associated with the LED 202.

Further, the monitoring module 204 may include a comparison module 206. The comparison module 206 may be configured to compare the power consumption of the LED 202 with a pre-determined threshold level. This threshold level may specify a given candela level which must be met by LED 202 installed on the locomotive 100. For example, as per regulations, the pre-determined threshold for the LEDs 202 used on the locomotive 100 for road service is approximately 200,000 candela. Moreover, the pre-determined threshold for the LEDs 202 used on the locomotive 100 for yard service is approximately 60,000 candela.

It should be noted that the sensed feedback at the pre-determined time of the power consumption of the LED 202, hereinafter referred to as instantaneous power consumption, may be used to determine the operational health of the LED 202 at the time the sensed feedback is measured. In one embodiment, based on the instantaneous power consumption of the LED 202, the monitoring module 204 may predict an occurrence of the failure of the LED 202. The prediction may provide an estimation of remaining life in a particular LED 202, or collective life remaining for the set or subset of the LEDs 202. Hence, in a situation wherein the intensity of the LED 202 is relatively near to the pre-determined threshold, thereby tending to failure, the monitoring module 204 may predict when the LED 202 will fail.

Referring to FIG. 2, the monitoring module 204 may also be coupled to a display module 208. The display module 208 may include at least one of an indicator light, a display gauge, and a monitor. In one embodiment, the display module 208 may be present in the crew cab 104 of the locomotive 100. The display module 208 may be configured to notify the operator in case of failure and/or weak output of the LED 202. The notification may be in the form of any suitable visual and/or auditory feedback, indicative of the failure of the single LED 202 or the multiple LEDs 202. Moreover, in one embodiment, the notification may be a warning to the operator based on the predicted failure of the LED 202.

It should be noted that the connections shown in FIG. 2 are merely on an exemplary basis. Other components not shown herein may also be part of the system. Moreover, in one embodiment, the monitoring module 204 may be invoked manually by the operator via suitable controls present in the crew cab 104. Alternatively, the monitoring module 204 may be automatically invoked after a pre-determined time period.

Further, the monitoring module 204 may embody a single microprocessor or multiple microprocessors that include a means for receiving the one or more signals indicative of the power consumption of the LED 202. Numerous commercially available microprocessors may be configured to perform the functions of the monitoring module 204. It should be appreciated that the monitoring module 204 may readily embody a general machine microprocessor capable of controlling other functions. A person of ordinary skill in the art will appreciate that the monitoring module 204 may additionally include other components and may also perform other functionality not described herein.

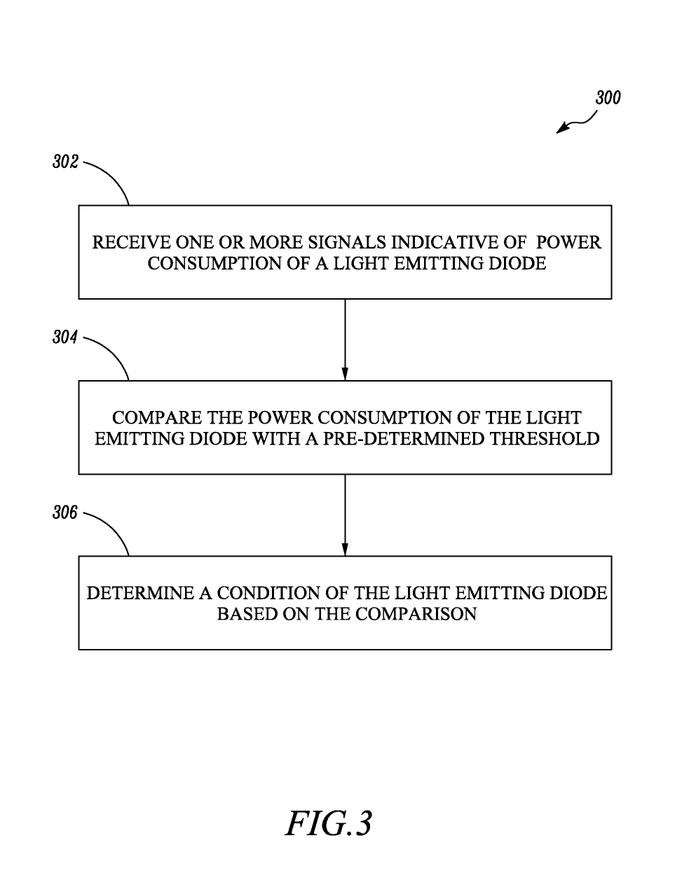

The method 300 for monitoring the operational health of the LED 202 will be described in connection with FIG. 3.

### INDUSTRIAL APPLICABILITY

The locomotives 100 used in road service, make use of standard dual, sealed beam, incandescent lights which are mounted together, either horizontally or vertically, on the front of the locomotive 100. However, the use of LEDs 202 is now beginning to replace the incandescent lights on the locomotive 100. Regulations require that the intensity of a headlight beam of each of the locomotives 100 used in road service be at least approximately 200,000 candela. Also, the intensity for the locomotives 100 used in yard service is desired to be approximately 60,000 candela. These intensity levels may serve as the pre-determined threshold parameter to be met during testing of the LED 202.

In the present disclosure, the monitoring module 204 may determine the intensity of the LED 202 based on the power consumption of the LED 202. The power consumption and/or the instantaneous power consumption of the LED 202 may provide relatively accurate indication of the operational health of the LED 202.

At step 302, the one or more signals indicative of the power consumption and/or the instantaneous power consumption of the LED 202 are received. These signals may include the voltage and current signals associated with the LED 202. The signals may be measured at the pre-determined time. Thereafter at step 304, the comparison module may compare the received signals with the pre-determined threshold.

At step 306, the monitoring module 204 may determine the condition of the LED 202 based on the comparison. In one embodiment, if the intensity estimated from the received signals is nearing the pre-determined threshold, then the monitoring module 204 may determine that the LED 202 is in a weak output state. If the intensity of the LED 202 is well below the pre-determined threshold then the monitoring module 204 may determine that the LED 202 has failed. In one embodiment, if the intensity estimated from the received signals is higher than the pre-determined threshold or close to failure, then the monitoring module 204 may predict when the LED 202 may fail. Moreover, on failure of the LED 202, the display module 208 may notify the operator of the failure using suitable feedback.

A person of ordinary skill in the art will appreciate that the monitoring module 204 may be utilized on an application using the LED 202. Although the disclosure described herein is in connection with the headlight 102 and/or the alerting lights on the locomotive 100, this application does not limit the scope of the disclosure.

Although the embodiments of this disclosure as described herein may be incorporated without departing from the scope of the following claims, it will be apparent to those skilled in the art that various modifications and variations can be made. Other embodiments will be apparent to those skilled in the art from consideration of the specification and practice of the disclosure. It is intended that the specification and examples be considered as exemplary only, with a true scope being indicated by the following claims and their equivalents.

What is claimed is:

1. A system comprising:
a light emitting diode;
a monitoring module communicably coupled to the light emitting diode, the monitoring module configured to:
receive one or more signals indicative of power consumption of the light emitting diode; and
determine a condition of the light emitting diode based, at least in part, on the received signals.

2. The system of claim 1 wherein the condition of the light emitting diode further includes a weak output state.

3. The system of claim 1 wherein the condition of the light emitting diode further includes a failure of the light emitting diode.

4. The system of claim 1 further including a display module communicably coupled the monitoring module.

5. The system of claim 4, wherein the display module is configured to notify an operator based on the condition of the light emitting diode.

6. The system of claim 1, wherein the one or more signals are received at a pre-determined time.

7. The system of claim 6, wherein the one or more signals include a voltage signal and a current signal associated with the light emitting diode at the pre-determined time.

8. The system of claim 6, wherein the monitoring module is further configured to predict an occurrence of a failure of the light emitting diode based on the signals received at the pre-determined time.

9. The system of claim 1, wherein the one or more signals include a voltage signal and a current signal associated the light emitting diode.

10. A method comprising:
receiving one or more signals indicative of power consumption of a light emitting diode;
comparing the power consumption of the light emitting diode with a pre-determined threshold; and
determining a condition of the light emitting diode based on the comparison.

11. The method of claim 10 further including notifying an operator based on the condition of the light emitting diode.

12. The method of claim 10 further including receiving the one or more signals at a pre-determined time.

13. The method of claim 12, wherein the one or more signals include a voltage signal and a current signal associated with the light emitting diode at the pre-determined time.

14. The method of claim 12 further including predicting an occurrence of a failure of the light emitting diode based on the signals received at the pre-determined time.

15. A locomotive comprising:
an engine;
a light having a light emitting diode;
a display module; and
a monitoring module communicably coupled to the light emitting diode and the display module, the monitoring module configured to:
receive one or more signals indicative of power consumption of the light emitting diode;
determine a condition of the light emitting diode based, at least in part, on the received signals; and
display a notification based on the condition of the light emitting diode.

16. The locomotive of claim 15, wherein the display module includes at least one of an indicator light, a display gauge, and a monitor.

17. The locomotive of claim 15, wherein the one or more signals are received at a pre-determined time.

18. The locomotive of claim 15, wherein the one or more signals include a voltage signal and a current signal associated with the light emitting diode at the pre-determined time.

19. The locomotive of claim 18, wherein the monitoring module is further configured to predict an occurrence an occurrence of a failure of the light emitting diode based on the signals received at the pre-determined time.

20. The locomotive of claim 15, wherein the one or more signals include a voltage signal and a current signal associated with the light emitting diode.
